(19) United States
(12) Patent Application Publication
(10) Pub. No.: US 2026/0142666 A1
(43) Pub. Date: May 21, 2026

(54) TRACK-AND-HOLD CIRCUIT HAVING PRE-CHARGING MOSFET CAPACITOR THEREOF FOR SHORTENING WAKE-UP DELAY TIME

(71) Applicant: PixArt Imaging Incorporation, Hsinchu (TW)

(72) Inventors: Kei-Tee Tiew, Penang (MY); Boon-Eu Seow, Penang (MY)

(21) Appl. No.: 19/449,218

(22) Filed: Jan. 14, 2026

Related U.S. Application Data
(63) Continuation-in-part of application No. 18/671,042, filed on May 22, 2024, now Pat. No. 12,549,190.

(51) Int. Cl. H03M 1/00

(52) U.S. Cl. CPC H03M 1/002

(57) ABSTRACT

A track-and-hold circuit includes a charge pump circuit and a bootstrapped switch. The charge pump circuit pumps a supply voltage into a pumped voltage higher than the supply voltage, and includes at least one MOSFET capacitor switched based on a clock signal, and a pre-charging switch coupled between a pull-up source and a body of the MOSFET capacitor. The pre-charging switch includes a native NMOS transistor and is switched based on the clock signal to pre-charge the body of the MOSFET capacitor, thereby reducing a wake-up delay time of the pumped voltage. The bootstrapped switch tracks and holds an input signal based on a bootstrapped driving signal to generate a track-and-hold output signal. The bootstrapped driving signal is generated based on a track-and-hold control signal related to the clock signal, the input signal, and the pumped voltage.

### CROSS REFERENCE

The present invention is a continuation-in-part application of US serial No. 18/671042, filed on May 22, 2024.

### BACKGROUND OF THE INVENTION

### FIELD OF INVENTION

The present invention relates to a track-and-hold circuit; particularly it relates to a track-and-hold circuit having pre-charging its MOSFET capacitor for shortening wake-up delay time. The present invention also relates to a track-and-hold circuit for use in data converters such as SAR ADC.

### DESCRIPTION OF RELATED ART

A track-and-hold circuit is one of the important blocks in low-voltage analog-to-digital converters (ADC), such as a successive approximation register (SAR) ADC or a pipelined ADC, and functions to stabilize the input signal prior to digitization, thereby enhancing the accuracy and efficiency of the conversion process. FIG. 1 shows a schematic diagram of a prior art track-and-hold circuit. The track-and-hold circuit 101 includes a charge pump circuit 110, a bootstrap driving circuit 120, and a bootstrapped switch M11. The charge pump circuit 110 operates by utilizing capacitors C1 and C2 along with switches M1 and M2 according to a clock signal for the charge pumping operation. capacitor C3 is used to generate the driving voltage and switching signal required for the bootstrap switch operation.

These capacitors are usually implemented using MIM (metal-insulator-metal), MOM (metal-oxide-metal) capacitors or N-Polycap (N-poly type of capacitor) capacitors. The layout area occupied by these types of the capacitors is the main disadvantage, which tremendously increases the total size of the SAR ADC, especially in the multichannel SAR ADC. Besides that, utilizing the N-Polycap or MIM capacitors in the track-and-hold circuit also causes extra wafer process cost.

Therefore, the MOSFET capacitors (e.g., PMOSFET) are then a preferred choice to reduce the layout area and the process cost. The disadvantage of using the MOSFET capacitors in the track-and-hold circuit is the “wake-up delay time” issue caused by the parasitic n-well diodes, formed by the n-well and p-substrate junctions, of the MOSFET capacitors.

Still referring to FIG. 1, the unwanted parasitic n-well diodes (e.g., DP1-DP3) appeared at the nodes N1, N2 and N3. These parasitic diodes have significant impact on the charging time of the capacitors at the nodes N1 and N2 of the cross-coupled clock booster (i.e., the charge pump 110), which consequently increases the wake-up delay time of the track-and-hold circuit. The parasitic n-well diodes of the MOS capacitors discharge the voltage at N1 and N2 to near ground voltage level before start-up, it therefore requires extra charging time when the clock toggles from logic “low” to logic “high”, during startup, to re-charge the capacitors at N1 and N2 in the cross-coupled pair.

FIG. 2 shows the simulation results of the wake-up delay time of the prior art track-and-hold circuit with MOS capacitors. In worst-case process corner, the wake-up delay time may be, unacceptably, up to 608us.

### SUMMARY OF THE INVENTION

From one perspective, the present invention provides a track-and-hold circuit comprising: a charge pump circuit configured to pump a supply voltage into a pumped voltage which is higher than the supply voltage, including: at least one metal-oxide-semiconductor field-effect transistor capacitor (MOSFET capacitor), switched based on a clock signal; and a pre-charging switch, coupled between a pull-up source and a body of the at least one MOSFET capacitor, wherein the pre-charging switch includes a native N-type metal-oxide-semiconductor field-effect transistor (native NMOS transistor), and wherein the pre-charging switch is switched based on the clock signal to conduct the pull-up source to pre-charge the body of the at least one MOSFET capacitor, thereby reducing a wake-up delay time of the pumped voltage; and a bootstrapped switch, configured to track and hold an input signal received from one end of the bootstrapped switch based on a bootstrapped driving signal, thereby generating a track-and-hold output signal on another end of the bootstrapped switch; wherein the bootstrapped driving signal is generated based on a track-and-hold control signal related to the clock signal, the input signal and the pumped voltage provided by the charge pump circuit.

In one embodiment, a first threshold voltage of the pre-charging switch is significantly lower than a second threshold voltage of a non-native N-type metal-oxide-semiconductor field-effect transistor (non-native NMOS transistor) in the track-and-hold circuit.

In one embodiment, the supply voltage serves as the pull-up source.

In one embodiment, the pre-charging switch is controlled to switch in synchronization with a pre-charging phase of the clock signal, during which a baseline voltage of a voltage across the at least one MOSFET capacitor is to be pulled down to logic low by the clock signal for charging the at least one MOSFET capacitor.

In one embodiment, a gate oxide layer of the pre-charging switch has a thickness greater than a thickness of a gate oxide layer of the non-native NMOS transistor in the track-and-hold circuit, such that a first gate voltage tolerance of the pre-charging switch is higher than a second gate voltage tolerance of the non-native NMOS transistor in the track-and-hold circuit.

In one embodiment, the charge pump circuit is configured as a voltage doubler, wherein the at least one MOSFET capacitor includes a first MOSFET capacitor and a second MOSFET capacitor, each configured to store charge and to be pumped to the pumped voltage, wherein the charge pump circuit further includes: a first switch and a second switch which are cross-coupled, wherein the first and the second switches are coupled to the first and second MOSFET capacitors respectively at respective source terminals thereof, and gates of the first and the second switches are cross-coupled to the second and the first MOSFET capacitors respectively; wherein the first MOSFET capacitor is switched by the clock signal and the second MOSFET capacitor is switched by an inverse of the clock signal, facilitating alternate charging and pumping cycles between the first and second MOSFET capacitors; wherein the pre-charging switch is configured to pre-charge one or both of the first and second MOSFET capacitors.

In one embodiment, the track-and-hold circuit further comprises a third switch and a third MOSFET capacitor which are coupled to the second MOSFET capacitor and are configured to generate and hold the pumped voltage, wherein the pre-charging switch is configured to pre-charge the first MOSFET capacitor, thereby balancing the capacitive loading between the first and the second MOSFET capacitors while providing the pumped voltage.

In one embodiment, the at least one MOSFET capacitor is implemented by the same type MOSFET device, formed in the same process steps, as at least one switch within the charge pump circuit.

In one embodiment, the pre-charging switch pre-charges the body of the at least one MOSFET capacitor during startup of the charge pump circuit, and is disabled when the pumped voltage is higher than a predetermined level or when a predetermined startup time has expired.

In one embodiment, the track-and-hold circuit is for use in a successive approximation register analog-to-digital converter (SAR ADC), wherein the SAR ADC includes a comparator, a SAR logic circuit and a digital-to-analog converter (DAC), wherein the track-and-hold circuit is configured to track and hold the input signal to generate the track-and-hold output signal, wherein the comparator, the SAR logic circuit and the DAC are configured to convert the track-and-hold output signal by successive approximation register conversion to generate a corresponding digital code.

In one embodiment, a gate of the pre-charging switch is formed without receiving a threshold voltage adjustment implantation that is received by a gate of the non-native NMOS transistor.

In one embodiment, the first threshold voltage is one-fifth or less of the second threshold voltage.

The track-and-hold circuit of the present invention circuit aims to mitigate the wake-up delay time while maintaining the all-CMOS circuit (i.e., using MOSFET capacitors), thereby reducing the chip layout area and the fabrication cost.

The objectives, technical details, features, and effects of the present invention will be better understood with regard to the detailed description of the embodiments below.

### BRIEF DESCRIPTION OF THE DRAWINGS

FIG. 1 shows a schematic diagram of a prior art track-and-hold circuit.

FIG. 2 shows a simulation waveform diagram of a prior art track-and-hold circuit.

FIG. 3 shows a schematic diagram of an embodiment of a track-and-hold circuit according to the present invention.

FIG. 4 shows a schematic diagram of an embodiment of a pre-charging circuit of a track-and-hold circuit according to the present invention.

FIG. 5 shows a schematic diagram of an embodiment of a pull-up circuit of a track-and-hold circuit according to the present invention.

FIG. 6 shows a schematic diagram of an embodiment of a clock generator circuit of a track-and-hold circuit according to the present invention.

FIG. 7 shows a simulation waveform diagram of an embodiment of a clock generator circuit of a track-and-hold circuit according to the present invention.

FIG. 8 shows a simulation waveform diagram of an embodiment of a track-and-hold circuit according to the present invention.

FIG. 9 shows a simulation waveform diagram of an embodiment of a track-and-hold circuit according to the present invention.

FIG. 10 shows a block diagram of an embodiment of a SAR ADC utilizing a track-and-hold circuit according to the present invention.

FIG. 11 illustrates a schematic diagram of a track-and-hold circuit and a pre-charging circuit thereof according to another embodiment of the present invention.

FIG. 12 illustrates a partial schematic diagram of a track-and-hold circuit according to another embodiment of the present invention.

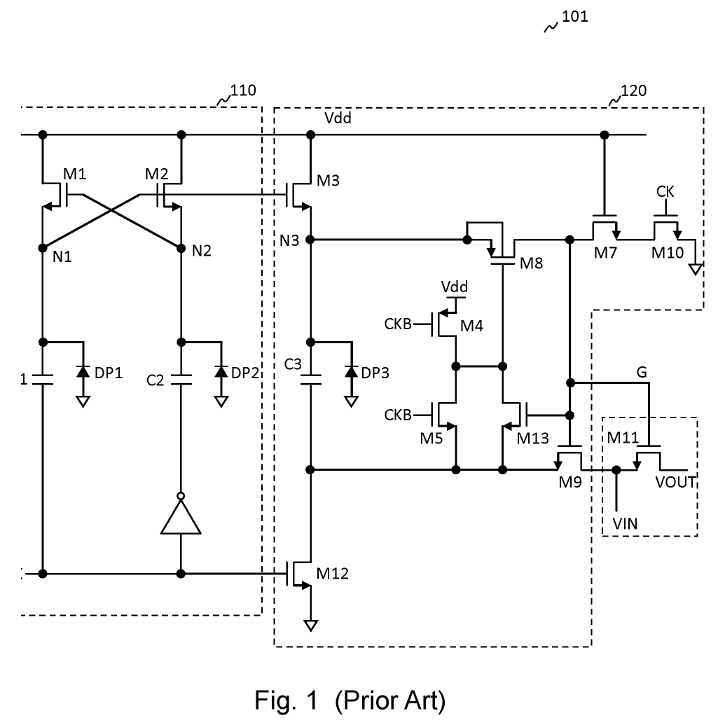

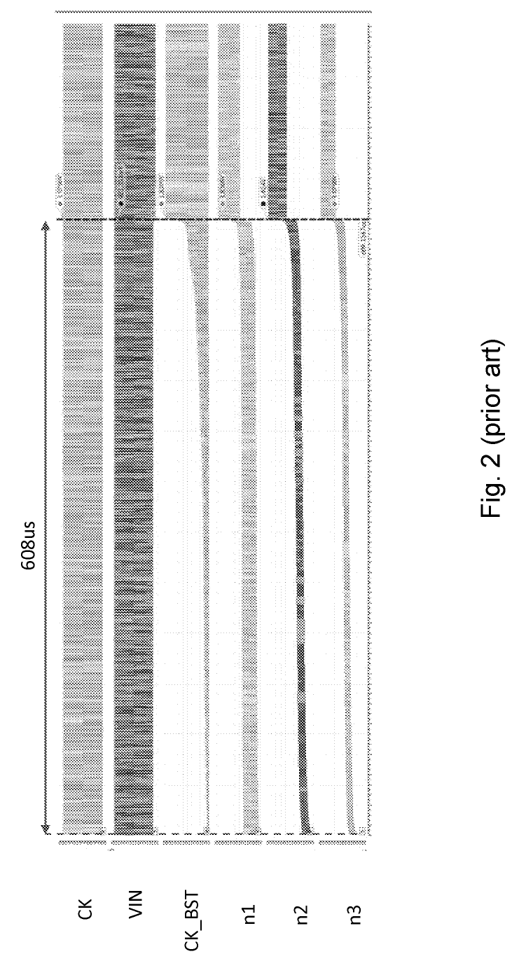

### DESCRIPTION OF THE PREFERRED EMBODIMENTS

The drawings as referred to throughout the description of the present invention are for illustration only, to show the interrelations between the circuits and the signal waveforms, but not drawn according to actual scale.

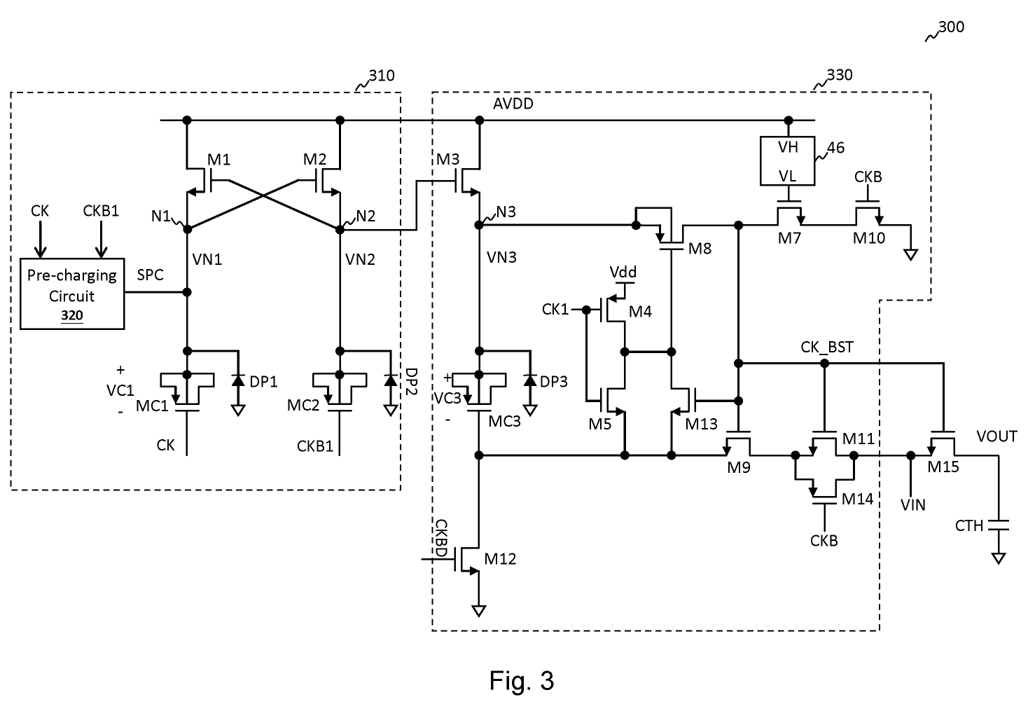

FIG. 3 shows a schematic diagram of an embodiment of a track-and-hold circuit according to the present invention. The track-and-hold circuit 300 comprises a charge pump circuit 310, a bootstrap driving circuit 330 and a bootstrapped switch M15.

The charge pump circuit 310 is configured to pump a supply voltage AVDD into a pumped voltage which is higher than the supply voltage AVDD.

In one embodiment, the charge pump circuit 310 includes at least one metal-oxide-semiconductor field-effect transistor capacitor (MOSFET capacitor) and a pre-charging circuit 320. The MOSFET capacitor is switched by a plurality of switches within the charge pump circuit based on a clock signal CK for pumping the supply voltage AVDD into the pumped voltage. The pre-charging circuit 320 is configured to pre-charge a body of the MOSFET capacitor based on a pre-charging signal SPC synchronous with the clock signal CK, thereby reducing a wake-up delay time of the pumped voltage.

The bootstrap driving circuit 330 is configured to generate a bootstrapped driving signal CK_BST, based on a track-and-hold control signal CK1, the input signal VIN and the pumped voltage provided by the charge pump circuit 310, to drive the bootstrapped switch M15. The bootstrapped switch M15 is configured to track and hold an analog input signal VIN received from one end of the bootstrapped switch M15 based on the bootstrapped driving signal CK_BST, thereby generating a track-and-hold output signal VOUT on another end of the bootstrapped switch M15. A holding capacitor CTH is configured to hold the track-and-hold output signal VOUT.

Still referring to FIG. 3, in one embodiment, the charge pump circuit 310 includes a voltage doubler. The aforementioned at least one MOSFET capacitor of the voltage doubler includes, in this embodiment, a first MOSFET capacitor MC1 and a second MOSFET capacitor MC2, each configured to store charge and to be pumped to the pumped voltage which is higher than the supply voltage AVDD. The voltage doubler (i.e., 310) further includes a pair of cross-coupled switches M1 and M2, wherein each switch is coupled to a corresponding one of the first and second MOSFET capacitors MC1 and MC2 at its source terminal. Gates of the switches M1 and M2 are cross-coupled to the second and the first MOSFET capacitors MC2 and MC1 respectively.

In this embodiment, the first MOSFET capacitor MC1 is switched by a clock signal CK and the second MOSFET capacitor MC2 is switched by an inverted clock signal CKB1 of the clock signal CK, facilitating alternate charging and pumping cycles between the two MOSFET capacitors.

The pre-charging circuit 320 is configured to pre-charge at least one of the MOSFET capacitor (e.g. MC1), reducing the wake-up delay time and thereby accelerating the voltage doubling effect. More specifically, during operation, when the first MOSFET capacitor MC1 is charged during one phase (e.g., logic low) of the clock signal CK, the second MOSFET capacitor MC2 is pumped up, contributing its stored charge to a higher voltage, and vice versa, effectively doubling the output voltage relative to the supply voltage AVDD, provided the amplitudes of the clock signals are also the same level of the supply voltage AVDD. During steady state, when the second MOSFET capacitor MC2 is pumped up (i.e., when CKB1 is high), the switches M1 and M3 are turned ON by the pumped voltage VN2, thereby charging the MOSFET capacitor MC1 through the switch M1 and charging the MOSFET capacitor MC3 through the switch M3.

Note that the aforementioned “pumped voltage” can be referred to as the voltages VN1, VN2 or VN3 on the nodes N1, N2 and N3 respectively, or can be referred to as the voltage across the MOSFET capacitor MC3, VC3.

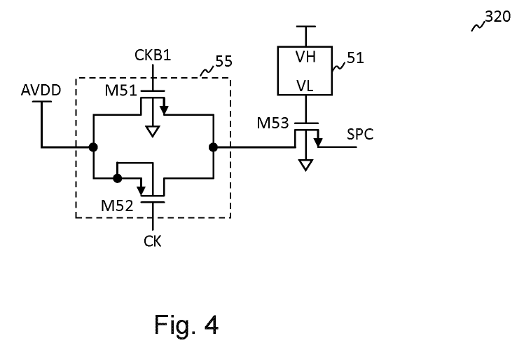

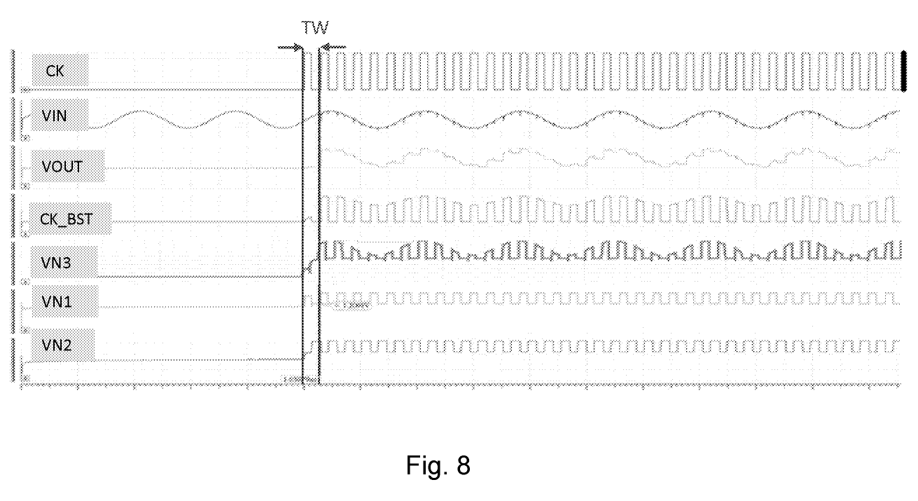

The wake-up delay time can be drastically improved by introducing the pre-charging circuit 320 to the all-CMOS (complementary MOS) charge pump circuit 310. Please still refer to FIG. 3, in conjunction with FIG. 4 showing a schematic diagram of an embodiment of a pre-charging circuit of a track-and-hold circuit according to the present invention and FIG. 8 which illustrates a simulation waveform diagram of an embodiment of a track-and-hold circuit according to the present invention. As shown in FIG. 4, the pre-charging circuit 320 includes a transmission gate 55 and an NMOS switch M53 that is always turned on. The transmission gate 55 includes pre-charging switches M51 and M52, which are an NMOS switch and a PMOS switch respectively, and are respectively controlled by an inverted clock signal CKB1 and a clock signal CK. The inverted clock signal CKB1 is an inverted signal of the clock signal CK. The pull-up circuit 51 is configured to control the NMOS switch M53. When CK is at logic low, the transmission gate 55 turns on and electrically connects a pull-up source to node N1, so that the voltage VN1 at the node N1 can maintain the charge level, thereby reducing the charging time at node N1 and significantly shortening the wake-up delay time. When CK is at logic high, the transmission gate 55 is off, it then electrically disconnects the pull-up source from the node N1. In one embodiment, the pull-up source can be the supply voltage AVDD.

Note that, in the embodiment as shown in FIG. 3, the sub-pumping circuit formed by the switch M3 and the MOSFET capacitor MC3 are coupled to the MOSFET capacitor MC2 at the node N2, while the pre-charging circuit 320 is configured to pre-charge the MOSFET capacitor MC1 at the node N1, thereby balancing the capacitive loading between the MOSFET capacitors MC1 and MC2 while providing the pumped voltage during the pumping operation.

In addition to the voltage doubler described above, the charge pump can be alternatively implemented with other types of switched-capacitor charge pump circuits. The pre-charging operation at the pumping capacitors is also applicable to other charge pump topologies.

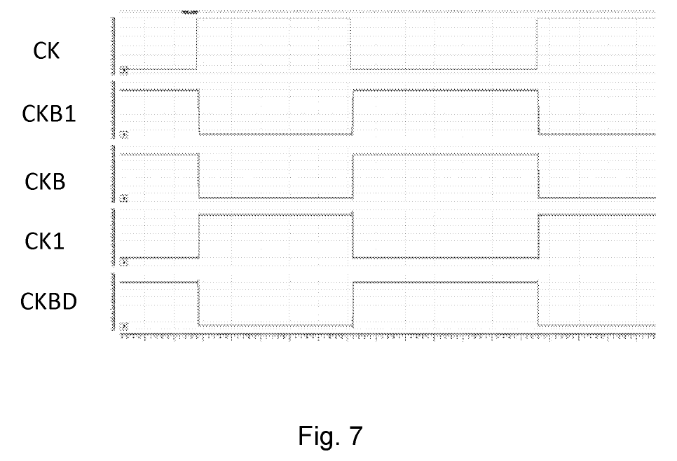

FIG. 6 shows a schematic diagram of an embodiment of a clock generator circuit of a track-and-hold circuit according to the present invention. FIG. 7 shows a simulation waveform diagram of an embodiment of a clock generator circuit of a track-and-hold circuit according to the present invention. In one embodiment, as shown in FIG. 6 and FIG. 7, the clock generator circuit is configured to generate related clock signals having different phases or driving capabilities. The clock generator circuit 30 is configured to generate a track-and-hold control signal CK1 which is a buffered in-phase version of the clock signal CK. The inverted clock signals CKB, CKB1 are two additional inverted versions of the clock signal CK. The clock signal CKBD is a non-overlapped inverted version of the clock signal CK.

Still referring to FIG. 4, in one embodiment, the transmission gate 55 is controlled to be ON in synchronization with a pre-charging phase of the clock signal CK (e.g., inverted phase of CK), during which a baseline voltage (e.g., the negative terminal voltage of MC1) of the voltage across the MOSFET capacitor MC1 is to be pulled down to logic low by the clock signal CK for charging the MOSFET capacitor MC1. That is, in this condition, the supply voltage AVDD provides a pre-charging signal SPC to charge the MOSFET capacitor MC1 through the transmission gate 55 and the NMOS switch M53, such that a pumped node voltage VN1 (i.e., a positive terminal of the MOSFET capacitor MC1) is pre-charged to the supply voltage AVDD. In one embodiment, the pre-charging operation stops when the transmission gate 55 is turned off after a baseline voltage across the MOSFET capacitor MC1 is elevated to pump the node voltage VN1.

Still referring to FIG. 4, the always-on NMOS switch M53 is to provide isolation between the output of the transmission gate 55 and the node N1. More specifically, the always-on NMOS switch 53 absorbs the injection charge from the transmission gate 55 when the transmission gate turns off and isolates the transmission gate 55 from node N1 so that the transmission gate 55 does not experience high voltage from the node N1. Note that the high voltage from the node N1 can be higher than an upper limit and damage the transistors M51 and M52 of the transmission gate 55.

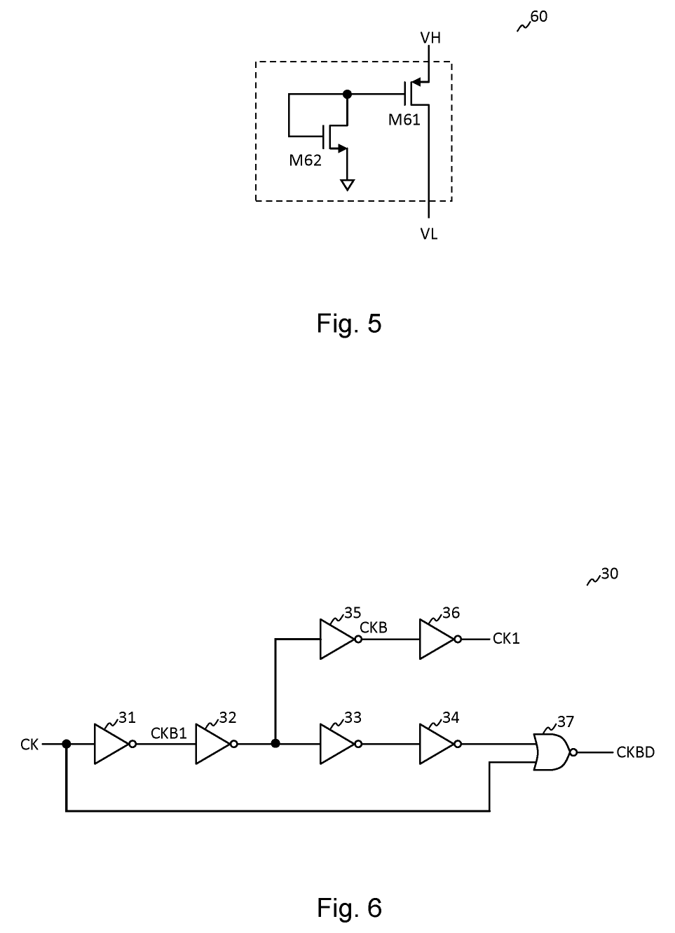

Still referring to FIG. 4, from one perspective, the always-on NMOS switch 53 is configured as a clamping transistor, biased by a predetermined voltage to maintain a voltage of the pre-charging switch M51 (or M52) not exceeding a predetermined upper limit. The predetermined voltage can be provided for example by a pull-up circuit as shown in FIG. 5. In one embodiment, the pull-up circuit 60 includes a PMOS switch M61, which is coupled between terminals VH and VL, and is controlled by a diode connected NMOS transistor M62. Note that the pull-up circuit 60 can also be employed for pulling up the voltage of a switch M7 within the bootstrap driving circuit 330 shown in FIG. 3.

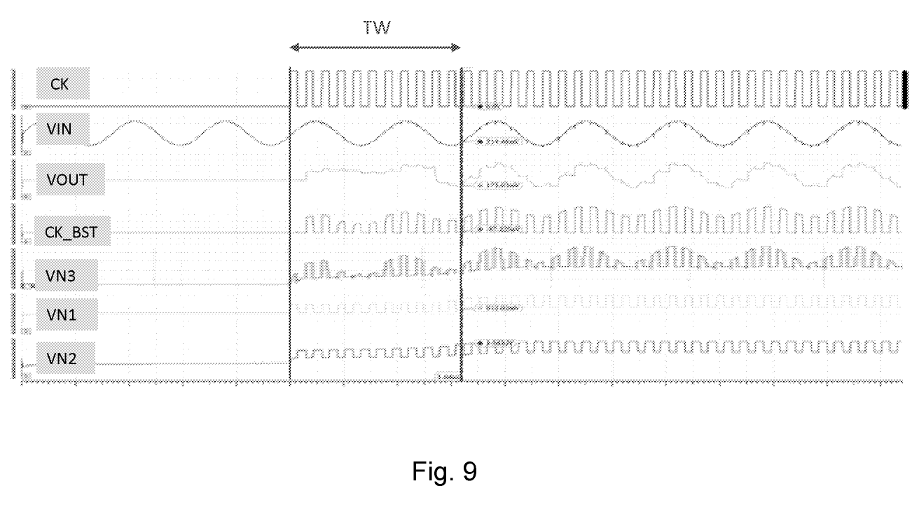

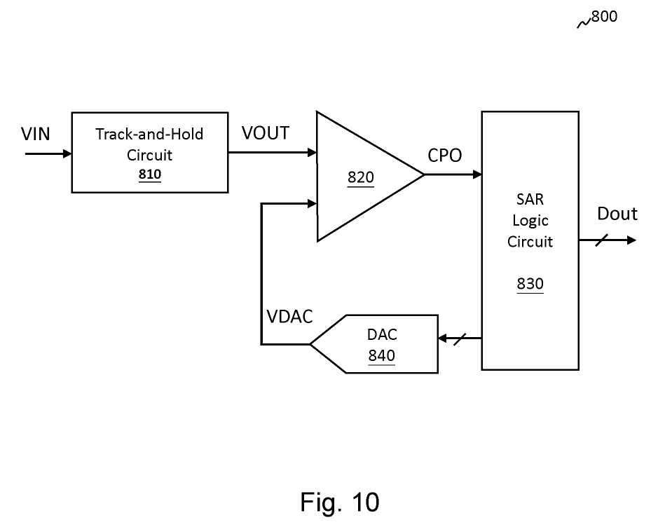

FIG. 8 and FIG. 9 show simulation waveform diagrams of embodiments, corresponding to typical and worst-case process corners respectively, of a track-and-hold circuit according to the present invention.

Displayed in FIG. 8 and FIG. 9 are the clock signal CK, the input signal VIN, the bootstrapped driving signal CK_BST, the voltages VN1-VN3 on nodes N1-N3 respectively. The simulation shows that the wake-up delay time TW can be reduced to as short as around 0.1 µs (FIG. 8) in typical process corner and around 1.0 µs in the worst-case process corner (slow-slow/1.08/-40˚C, FIG. 9). Compared to the aforementioned prior art, an improvement of nearly three orders of magnitude is achieved by the proposed track-and-hold circuit according to the present invention.

Still referring to FIG. 8 and FIG. 9, from one perspective, the bootstrapped driving signal CK_BST is synchronous with the clock signal CK, while bootstrapped by the input signal VIN and related clock signals (such as CKBD, CKB and CK1), such that the gate-source voltage of the bootstrapped switch M15 can be relatively constant when being turned on.

It is noteworthy that the employment of the pre-charging circuit of the present invention enables the track-and-hold circuit to utilize MOSFET capacitors as pumping capacitors, which reduces the chip layout area and the fabrication cost. In one embodiment, the MOSFET capacitor (MC1, MC2 or MC3) is implemented by the same type MOSFET device, formed in the same process steps, of at least one switch (e.g., M1, M2 or M3) within the charge pump circuit 310. In one embodiment, the MOSFET capacitor is implemented by a PMOSFET (P-type MOSFET) in the CMOS process for implementing other CMOS devices building the track-and-hold circuit.

In one embodiment, the pre-charging circuit 320 pre-charges the body of the MOSFET capacitor during the startup (or wake-up from a long sleep state) of the charge pump circuit 310, and can be disabled when the pumped voltage is higher than a predetermined level or when a predetermined startup time has expired.

FIG. 10 shows a block diagram of an embodiment of a Successive Approximation Register Analog-to-Digital Converter (SAR ADC) utilizing a track-and-hold circuit according to the present invention. In this embodiment, the SAR ADC 800 includes a track-and-hold circuit 810, a comparator 820, a SAR logic circuit 830 and a Digital-to-Analog Converter (DAC) 840. The track-and-hold circuit 810 for example corresponds to the embodiment of FIG. 3. The track-and-hold circuit 810 tracks and holds the input signal VIN to generate a track-and-hold output signal VOUT. The comparator 820, the SAR logic circuit 830 and the DAC 840 are configured to convert the track-and-hold output signal VOUT using successive approximation register conversion to generate a corresponding digital code Dout, which is known in the art and therefore not elaborated in detail here.

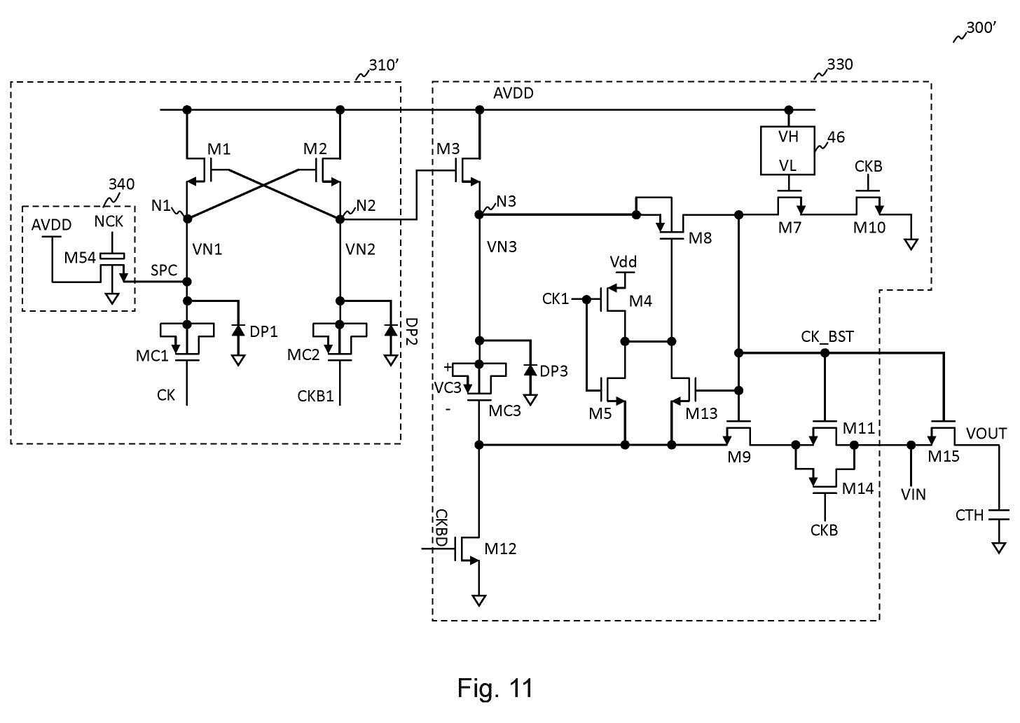

FIG. 11 illustrates a schematic diagram of a track-and-hold circuit and a pre-charging circuit thereof according to another embodiment of the present invention. The track-and-hold circuit 300’ shown in FIG. 11 is similar to the track-and-hold circuit 300 of FIG. 3, with a primary difference being that the pre-charging circuit 340 of the charge pump circuit 310’ is employed in FIG. 11.

Specifically, the pre-charging circuit 340 of FIG. 11 includes a pre-charging switch 54, which is implemented using a native N-type metal-oxide-semiconductor field-effect transistor (i.e., a native NMOS transistor) to perform a pre-charging operation. A native NMOS transistor refers to an NMOS transistor whose gate is formed without a threshold voltage adjustment implantation. Therefore, compared with a non-native N-type metal-oxide-semiconductor field-effect transistor (non-native NMOS transistor) in the track-and-hold circuit (for example, the NMOS transistor M51 in FIG. 4, or M1, M2, and M3 in FIG. 3), the native NMOS transistor has a significantly lower threshold voltage.

In one embodiment, the threshold voltage of the native NMOS transistor M54 is, for example, one-fifth or less of the threshold voltage of the non-native NMOS transistor. In one embodiment, the threshold voltage of the native NMOS transistor M54 is, for example, approximately 0.1 volts. It should be noted that a gate of the non-native NMOS transistor receives a threshold voltage adjustment implantation, and therefore has a threshold voltage higher than that of the native NMOS transistor.

In addition, in one embodiment, thickness of a gate oxide layer of the native NMOS transistor M54 is greater than that of the non-native NMOS transistor. As a result, the native NMOS transistor M54 exhibits a higher gate voltage tolerance between its gate and drain or between its gate and source, and is capable of withstanding a high voltage that may be generated at the node N1 during operation of the charge pump. Since, in FIGS. 3 and 11, a voltage VN1 at the node N1 is boosted to a level higher than AVDD during a pumping phase, the high-voltage tolerance of the transistor M54 ensures that the transistor M54 is not damaged by overvoltage while providing a pre-charging path.

In one embodiment, the native NMOS transistor M54 is, for example, implemented using an input/output device provided in a manufacturing process of the track-and-hold circuit 300’, and is formed by layout such that its gate does not receive the threshold voltage adjustment implantation using an existing mask for the threshold voltage adjustment implantation step. Accordingly, the native NMOS transistor M54 can be implemented without adding additional photomasks or process steps.

In this embodiment, one terminal of the native NMOS transistor M54 is coupled to the supply voltage AVDD, and another terminal thereof is coupled to the node N1. When a gate voltage of the native NMOS transistor M54 is driven to a conductive state at, for example, a level of AVDD, a source voltage thereof (that is, a voltage VN1 at the node N1) can reach a value corresponding to a difference between AVDD and a threshold voltage of the transistor. Since the native NMOS transistor M54 has a low threshold voltage characteristic, the source voltage thereof can be close to AVDD. Accordingly, the voltage VN1 at the node N1 can be pre-charged to a level close to AVDD, thereby effectively reducing a wake-up delay time TW of the charge pump and further accelerating an overall startup speed of the charge pump.

In the pre-charging circuit 340 shown in FIG. 11, the native NMOS transistor M54 is controlled by a control signal NCK. In one embodiment, the control signal NCK may, for example, correspond to the inverted clock signal CKB1 shown in FIGS. 3 and 6.

More specifically, when the clock signal CK is at a logic low level, the control signal NCK is at a logic high level, thereby turning on the native NMOS transistor M54. As a result, a low-impedance path is formed between a drain terminal of the native NMOS transistor M54 (coupled to the supply voltage AVDD) and a source terminal thereof (coupled to the node N1), so as to generate a pre-charging signal SPC and to rapidly pre-charge the node N1 to a voltage level close to AVDD.

Conversely, when the clock signal CK transitions to a logic high level, the control signal NCK becomes a logic low level, thereby turning off the native NMOS transistor M54 to isolate the supply voltage AVDD from the node N1. Accordingly, during operation of the charge pump, a voltage VN1 at the node N1 is prevented from being fed back to the supply voltage AVDD, thereby ensuring circuit safety and stability.

As shown in the embodiment of FIG. 11, the pre-charging switch can be implemented by a single native NMOS transistor M54, and thus provides advantages including simple control, high voltage tolerance, compatibility with a manufacturing process of other devices, and no requirement for additional process steps.

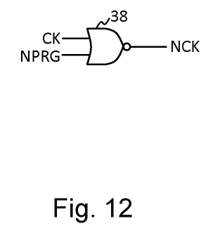

FIG. 12 illustrates a partial schematic diagram of a track-and-hold circuit 300’ according to another embodiment of the present invention. Compared with the embodiment shown in FIG. 11, the embodiment of FIG. 12 further includes a NOR gate 38 configured to control whether a pre-charging function is enabled, such that the pre-charging circuit 340 has flexibility to be selectively enabled or disabled.

As shown in FIG. 12, the NOR gate 38 has two input terminals configured to receive a clock signal CK and a pre-charging inverted control signal NPRG, respectively. In this embodiment, an output of the NOR gate 38 corresponds to and is used as the control signal NCK of the native NMOS transistor M54.

In this embodiment, when the pre-charging inverted control signal NPRG is at a logic low level (for example, logic “0”), the output of the NOR gate 38 (that is, the control signal NCK) becomes an inverted signal of the clock signal CK, which is functionally equivalent to the inverted clock signal CKB1 of FIG. 3 or FIG. 6 described above. Accordingly, in this condition, the native NMOS transistor M54 is adaptively turned on as described in the embodiment of FIG. 11 to perform a pre-charging operation, such that the voltage VN1 at the node N1 is rapidly charged to AVDD, thereby achieving an effect of reducing the wake-up delay time TW.

Conversely, when the pre-charging inverted control signal NPRG is at a logic high level (for example, logic “1”), the control signal NCK is forced to remain at a logic low level, thereby keeping the native NMOS transistor M54 turned off, which is equivalent to disabling the pre-charging circuit 340. In this embodiment, the pre-charging function can be selectively enabled or disabled by controlling the pre-charging inverted control signal NPRG according to an actual operating mode or different requirements on power consumption and startup speed in various application scenarios.

The present invention has been described in considerable detail with reference to certain preferred embodiments thereof. It should be understood that the description is for illustrative purpose, not for limiting the broadest scope of the present invention. It is not limited for each of the embodiments described hereinbefore to be used alone; under the spirit of the present invention, two or more of the embodiments described hereinbefore can be used in combination. For example, two or more of the embodiments can be used together, or, a part of one embodiment can be used to replace a corresponding part of another embodiment. Furthermore, those skilled in this art can readily conceive variations and modifications within the spirit of the present invention. For example, to perform an action “according to” a certain signal as described in the context of the present invention is not limited to performing an action strictly according to the signal itself, but can be performing an action according to a converted form or a scaled-up or down form of the signal, i.e., the signal can be processed by a voltage-to-current conversion, a current-to-voltage conversion, and/or a ratio conversion, etc. before an action is performed. The spirit of the present invention should cover all such and other modifications and variations, which should be interpreted to fall within the scope of the following claims and their equivalents.

What is claimed is:

1. A track-and-hold circuit comprising:
a charge pump circuit configured to pump a supply voltage into a pumped voltage which is higher than the supply voltage, including:
at least one metal-oxide-semiconductor field-effect transistor capacitor (MOSFET capacitor), switched based on a clock signal; and
a pre-charging switch, coupled between a pull-up source and a body of the at least one MOSFET capacitor, wherein the pre-charging switch includes a native N-type metal-oxide-semiconductor field-effect transistor (native NMOS transistor), and wherein the pre-charging switch is switched based on the clock signal to conduct the pull-up source to pre-charge the body of the at least one MOSFET capacitor, thereby reducing a wake-up delay time of the pumped voltage; and
a bootstrapped switch, configured to track and hold an input signal received from one end of the bootstrapped switch based on a bootstrapped driving signal, thereby generating a track-and-hold output signal on another end of the bootstrapped switch;
wherein the bootstrapped driving signal is generated based on a track-and-hold control signal related to the clock signal, the input signal and the pumped voltage provided by the charge pump circuit.

2. The track-and-hold circuit of claim 1, wherein a first threshold voltage of the pre-charging switch is significantly lower than a second threshold voltage of a non-native N-type metal-oxide-semiconductor field-effect transistor (non-native NMOS transistor) in the track-and-hold circuit.

3. The track-and-hold circuit of claim 1, wherein the supply voltage serves as the pull-up source.

4. The track-and-hold circuit of claim 1, wherein the pre-charging switch is controlled to switch in synchronization with a pre-charging phase of the clock signal, during which a baseline voltage of a voltage across the at least one MOSFET capacitor is to be pulled down to logic low by the clock signal for charging the at least one MOSFET capacitor.

5. The track-and-hold circuit of claim 2, wherein a gate oxide layer of the pre-charging switch has a thickness greater than a thickness of a gate oxide layer of the non-native NMOS transistor in the track-and-hold circuit, such that a first gate voltage tolerance of the pre-charging switch is higher than a second gate voltage tolerance of the non-native NMOS transistor in the track-and-hold circuit.

6. The track-and-hold circuit of claim 1, wherein the charge pump circuit is configured as a voltage doubler, wherein the at least one MOSFET capacitor includes a first MOSFET capacitor and a second MOSFET capacitor, each configured to store charge and to be pumped to the pumped voltage, wherein the charge pump circuit further includes:
a first switch and a second switch which are cross-coupled, wherein the first and the second switches are coupled to the first and second MOSFET capacitors respectively at respective source terminals thereof, and gates of the first and the second switches are cross-coupled to the second and the first MOSFET capacitors respectively;
wherein the first MOSFET capacitor is switched by the clock signal and the second MOSFET capacitor is switched by an inverse of the clock signal, facilitating alternate charging and pumping cycles between the first and second MOSFET capacitors;
wherein the pre-charging switch is configured to pre-charge one or both of the first and second MOSFET capacitors.

7. The track-and-hold circuit of claim 6, further comprising a third switch and a third MOSFET capacitor which are coupled to the second MOSFET capacitor and are configured to generate and hold the pumped voltage, wherein the pre-charging switch is configured to pre-charge the first MOSFET capacitor, thereby balancing the capacitive loading between the first and the second MOSFET capacitors while providing the pumped voltage.

8. The track-and-hold circuit of claim 1, wherein the at least one MOSFET capacitor is implemented by the same type MOSFET device, formed in the same process steps, as at least one switch within the charge pump circuit.

9. The track-and-hold circuit of claim 1, wherein the pre-charging switch pre-charges the body of the at least one MOSFET capacitor during startup of the charge pump circuit, and is disabled when the pumped voltage is higher than a predetermined level or when a predetermined startup time has expired.

10. The track-and-hold circuit of claim 1, wherein the track-and-hold circuit is for use in an analog-to-digital converter (ADC), wherein the track-and-hold circuit is configured to track and hold the input signal to generate the track-and-hold output signal, wherein the ADC is configured to convert the track-and-hold output signal to generate a corresponding digital code.

11. The track-and-hold circuit of claim 10, wherein the ADC is a successive approximation register analog-to-digital converter (SAR ADC), wherein the SAR ADC includes a comparator, a SAR logic circuit and a digital-to-analog converter (DAC), wherein the comparator, the SAR logic circuit and the DAC are configured to convert the track-and-hold output signal by successive approximation register conversion to generate the corresponding digital code.

12. The track-and-hold circuit of claim 2, wherein a gate of the pre-charging switch is formed without receiving a threshold voltage adjustment implantation that is received by a gate of the non-native NMOS transistor.

13. The track-and-hold circuit of claim 2, wherein the first threshold voltage is one-fifth or less of the second threshold voltage.
